(19) United States
(12) Patent Application Publication
(10) Pub. No.: US 2026/0133498 A1
(43) Pub. Date: May 14, 2026

(54) GRAYSCALE LITHOGRAPHY MASK

(71) Applicant: COMMISSARIAT A L'ENERGIE ATOMIQUE ET AUX ENERGIES ALTERNATIVES, Paris (FR)

(72) Inventors: Ujwol PALANCHOKE, Grenoble Cedex 09 (FR); Api WARSONO, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/383,992

(22) Filed: Nov. 10, 2025

(30) Foreign Application Priority Data
Nov. 14, 2024 (FR) FR2412426

(51) Int. Cl. G03F 7/00; G03F 1/38

(52) U.S. Cl. CPC G03F 7/70416; G03F 1/38

(57) ABSTRACT

A grayscale lithography mask intended to diffract an insolation radiation of a photosensitive resin. The insolation radiation, of wavelength λ, is emitted by a light source having a coherence σ and a numerical aperture NA. The mask extends mainly along a horizontal plane perpendicular to a main direction of the insolation radiation of the photosensitive resin through the mask. The mask includes a plurality of zones which are opaque to the radiation, the plurality of opaque zones comprising first opaque zones and second opaque zones, the first opaque zones being organised along a pitch array P₁ in the horizontal plane and the second opaque zones being organised along a pitch array P₂ in the horizontal plane, such that P₁<P_{Rayleigh} and P₂≥P_{Rayleigh}, with P_{Rayleigh}=λ((1+σ)*NA).

### TECHNICAL FIELD

The present invention relates to the field of photolithography, more specifically that of grayscale lithography. The invention relates quite specifically to the mask used in this technique. It relates, in particular, to manufacturing hierarchical three-dimensional structures, i.e. structures having several structuration levels.

### PRIOR ART

Three-dimensional structures and more specifically structures have several structuration levels have formed the subject of the last few years of numerous studies having demonstrated their interest in applications as diverse as antireflection devices, self-cleaning surfaces, hydrophobic or hydrophilic surfaces or also functional surfaces for biodetection.

There are several lithography techniques enabling the manufacture of such structures, in particular, structures having a microstructuration and a nanostructuration. Among these techniques, for example, there is nanoprinting lithography (U.S. Pat. No. 8,636,937 B2, US 2012/0268822 A1), selective-repetitive lithography, see for example U.S. Pat. No. 11,037,794 B2), or also block copolymer lithography (KR102523636 B1).

These different techniques are not, however, satisfactory, as they require numerous lithography steps. For example, to achieve the different structuration levels by nanoprinting, several master moulds must be manufactured and used during the 3D structure manufacturing process. Concerning selective-repetitive lithography, it is necessary to protect by a mask or a layer for protecting the structures formed after each structuration step. Finally, block copolymer lithography only makes it possible to perform a nanostructuration and must be combined with another lithography technique to perform the microstructuration.

20) There is thus a need for simplify the manufacture of structures having several structuration levels. The present invention is proposed to respond to this need.

### SUMMARY

To achieve this aim, according to an embodiment, the invention relates to a method for insolating a photosensitive resin comprising the following steps:
providing a photosensitive resin,
exposing the photosensitive resin to an insolation radiation having been emitted by a light source having a coherence σ and a numerical aperture NA, the insolation radiation having a wavelength λ,
developing the photosensitive resin.

The exposure of the photosensitive resin to the insolation radiation is done through a grayscale lithography mask extending mainly along a horizontal plane defined by a first direction and a second direction, the horizontal plane being perpendicular to a main direction of the insolation radiation of the photosensitive resin through the mask. According to the invention, the mask comprises a plurality of zones which are opaque to the radiation, the plurality of opaque zones comprising first opaque zones and second opaque zones, the first opaque zones being organised along a pitch array P₁ in the horizontal plane and the second opaque zones being organised along a pitch array P₂ in the horizontal plane (XY), such that P₁<P_{Rayleigh} and P₂≥P_{Rayleigh}, with

$${P}_{Rayleigh} = \frac{1}{1 + σ} * \frac{λ}{N A}$$

such that, after the development of the photosensitive resin, this has a first structuration level and a second structuration level superimposed on one another.

P_{Rayleigh} is the yield below which a pitch array P does not diffract the incident radiation (diffraction order 0), and above which it diffracts it (diffraction order 1 or more). Thus, at least one array of opaque zones letting the radiation pass through without diffracting it and at least one array of opaque zones diffracting the radiation are present within the mask according to the invention.

It appeared that combining these two types of arrays makes it possible, in one single step, to insolate the resin layer, such that the latter, once developed, has two structuration levels: a first structuration level, called microstructuration, induced by the array of first opaque zones, and a second structuration level, called nanostructuration, induced by the array of second opaque zones. These two structuration levels are superimposed.

Naturally, it is possible to add other arrays of opaque zones, in order to add structuration levels to the final resin layer.

The invention thus makes it possible to form complex and precise shapes in the resin layer, and this, in one single lithography cycle and development of the resin. The invention therefore enables a simplification of the manufacture of structures having several structuration levels.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIGS. 1A to 1D represent grayscale lithography masks and views under the scanning electron microscope of resins insolated through these masks then developed. FIGS. 1A and 1B relate to the manufacture of 3D structures having plates at different heights.

FIGS. 1C and 1D relate to the manufacture of 3D microlenses having a dome shape.

FIGS. 2A to 2H illustrate an example in which the mask comprises two regular arrays with P₁<P_{Rayleigh}, P₂≥P_{Rayleigh} and P₂=2*P₁.

FIGS. 3A to 3H illustrate an example in which the mask comprises two regular arrays of opaque zones with P₁<P_{Rayleigh}, P₂≥P_{Rayleigh} and P₂=3*P₁.

FIGS. 4A to 4E illustrate an example in which the mask comprises two regular arrays of opaque zones with P₁<P_{Rayleigh}, P₂≥P_{Rayleigh} and P₂=2.5*P₁.

FIGS. 5A to 5E illustrate an example in which the mask comprises three regular arrays of opaque zones with P₁<P_{Rayleigh}, P₂, P₃≥P_{Rayleigh} and P₂=2*P₁ et P₃=3*P₁.

FIGS. 6A to 9D illustrate an example in which the mask comprises one irregular array of opaque zones with local augmentation of the pitch.

FIGS. 10A to 10D illustrate an example in which the mask comprises one irregular array of opaque zones with local diminution of the pitch.

FIGS. 11A to 11G illustrate an example in which the mask comprises a superimposition of one irregular array of opaque zones with P₁<P_{Rayleigh} and of one regular array of opaque zones with P₂≥P_{Rayleigh}.

FIGS. 12A to 12F illustrate an example in which the mask comprises the superimposition of one irregular array with P₁<P_{Rayleigh} and of one cross-shaped regular array with P₂≥P_{Rayleigh}.

FIGS. 13A to 13H illustrate an example in which the mask comprises a superimposition of one irregular array with P₁<P_{Rayleigh} and of two regular arrays with P₂, P₃≥P_{Rayleigh}, one of which cross-shaped.

FIG. 14 is a cross-sectional view of a grayscale lithography mask being used to insolate a photosensitive resin.

The drawings are given as examples and are not limiting of the invention. They constitute principle schematic representations intended to facilitate the understanding of the invention and are not necessarily to the scale of practical applications. In particular, the dimensions are not representative of reality.

### DETAILED DESCRIPTION

Before starting a detailed review of embodiments of the invention, optional features are stated below, which can optionally be used in association or alternatively:

According to an embodiment, the pitch P₁ is constant over the entire array of first opaque zones. It is also possible that the pitch P₁ varies within the array of first opaque zones, while verifying the condition P₁<P_{Rayleigh} over the entire array. According to an embodiment, the pitch P₂ is constant over the entire array of second opaque zones. It is also possible that the pitch P₂ varies within the array of second opaque zones, while verifying the condition P₂≥P_{Rayleigh} over the entire array.

For example, P₁ can be between 100 and 300 nm. The first opaque zones moreover have a first characteristic dimension CD1 (typically the side of the square in the case of square opaque zones). CD1 can, for example, be greater than 40 nm and/or less than P₁.

For example, P₂ can be greater than 300 nm. The second opaque zones moreover have a second characteristic dimension CD2. CD2 can, for example, be greater than 40 nm and/or less than P₂.

Preferably, P₂ is at least 1.5 times greater than P₁, preferably at least twice greater.

According to an embodiment, the first opaque zones are substantially identical to one another. Quite specifically, the first opaque zones can be identical to one another in shape and in dimensions.

According to an embodiment, the first opaque zones have dimensions which are distinct from one another. They can, in particular, have shapes or dimensions which are distinct from one another. This can, in particular, enable a microstructuration of the insolated resin layer, for example, a dome-shaped microstructuration.

According to an embodiment, the second opaque zones are substantially identical to one another. Quite specifically, the second opaque zones can be identical to one another in shape and in dimensions.

According to an embodiment, some of the first opaque zones and second opaque 20) zones are at least partially combined.

According to an example, P₂=2*m*P₁, m being an integer.

According to an example, P₂=3*m*P₁, m being an integer.

According to an example, P₂=2.5*m*P₁, m being an integer.

According to an embodiment, the plurality of opaque zones further comprises third opaque zones organised along a pitch array P₃ in the horizontal plane (XY), P₃ being distinct from P₁ and from P₂.

According to an example, P₃≥P_{Rayleigh}.

According to an example, P₃=3*n*P₁, n being an integer.

According to an embodiment, the plurality of opaque zones allows at least one first symmetry plane perpendicular to the horizontal plane.

According to an embodiment, the second opaque zones allow at least one first symmetry plane perpendicular to the horizontal plane. This makes it possible to perform a nanostructuration of the resin having a symmetry plane.

According to an embodiment, the first opaque zones allow at least one first symmetry plane perpendicular to the horizontal plane. This makes it possible to perform a microstructuration of the resin having a symmetry plane.

According to an embodiment, the plurality of opaque zones allows at least one second symmetry plane perpendicular to the first symmetry plane and to the horizontal plane.

According to an embodiment, the second opaque zones allow at least one second symmetry plane perpendicular to the first symmetry plane and to the horizontal plane. This makes it possible to perform a nanostructuration of the resin having two symmetry planes.

According to an embodiment, the first opaque zones allow at least one second symmetry plane perpendicular to the first symmetry plane and to the horizontal plane. This makes it possible to perform a microstructuration of the resin having two symmetry planes.

According to an example, P₁ is less than or equal to 300 nm, for example, equal to 200 nm.

According to an example, P₂ is greater than or equal to 400 nm, for example, equal to 400 nm, 500 nm or 600 nm.

In the scope of the present invention, resin is qualified as an organic or organomineral material being able to be shaped by an exposure to an electron, photon, X-ray beam, a light beam in the ultraviolet range, extreme ultraviolet (EUV) or deep ultraviolet (deep UV) typically in the range of wavelengths of 193 nm to 248 nm, the emission lines from a mercury lamp, that is: 365 nm for the I line, 435 nm for the G line and 404 nm for the H line.

The invention is also applied to positive resins, i.e. the exposed part of which becomes soluble to the revealer and where the unexposed part remains insoluble, and to negative resins, i.e. the unexposed part of which becomes soluble to the revealer and where the exposed part remains insoluble.

The contrast of a resin, commonly referenced y, conveys the effectiveness of the behaviour referenced in literature as the resin “yield”. The larger the contrast is, the more a low dose variation is necessary, such that the resin passes from a state in which it cannot be developed to a state in which it can be developed (or conversely for a negative resin). The value of the contrast y of a resin, that it is of positive or negative tonality, is generally determined by the gradient of the curve according to the following equation:

$$\frac{e}{{e}_{0}} = γ ln ( \frac{{D}_{0}}{D} ) ,$$

where e is the thickness of the resin film after exposure and development, e₀ is the thickness of the initial resin film, D is the dose of exposure applied and D₀ is the dose at which the entire thickness of the film is developed.

By “nature” of a material such as a resin, this means its chemical composition, i.e. the nature and the proportion of the species constituting the material. Two layers are considered as made from one same resin if they have the same chemical composition.

In the present description, dose is qualified as a quantity of energy received by a resin per surface unit. This energy can be in the form of photons (photolithography) for a photosensitive resin. It is thus the product of the intensity of the incident light radiation (generally expressed in Watt/m²) and of the duration of exposure (expressed in seconds). The dose is thus usually expressed in Joules per m², or more often in milli Joules (mJ) per cm⁻² (10⁻⁴ m²) or also in mJ/m². This energy can also be in the form of electrons (electron lithography) for an electrosensitive resin. The dose is thus usually expressed in Coulombs per m², or more often in micro Coulombs (μC) per cm⁻² (10⁻² m²), that is in μC/m².

By a parameter “substantially equal to/greater than/less than” a given value, this means that this parameter is equal to/greater than/less than the given value, plus or minus 20%, even 10%, of this value. By a parameter “substantially between” two given values, this means that this parameter is, as a minimum, equal to the smallest given value, plus or minus 20%, even 10%, of this value, and as a maximum, equal to the greatest given value, plus or minus 20%, even 10%, of this value.

In the present patent application, preferably “thickness” will be referred to for a layer, and “height” for a structure or a device. The thickness is taken along a direction normal to the main extension plane of the layer, and the height is taken perpendicularly to the horizontal plane XY. Thus, a layer typically has a thickness along the so-called vertical direction Z, when it extends mainly along the horizontal plane XY. The relative terms “on”, “under”, “underlying” preferably refer to positions taken along the vertical direction Z.

A first aim of the present invention relates to a photolithography mask, quite specifically adapted to grayscale lithography.

Grayscale lithography is a photolithography technique enabling the production of three-dimensional (3D) microstructures in one single lithography and development step. It is particularly used in the manufacture of optical microelements, MEMS (microelectromechanical systems), MOEMS (microoptoelectromechanical systems) microfluid devices or also textured surfaces.

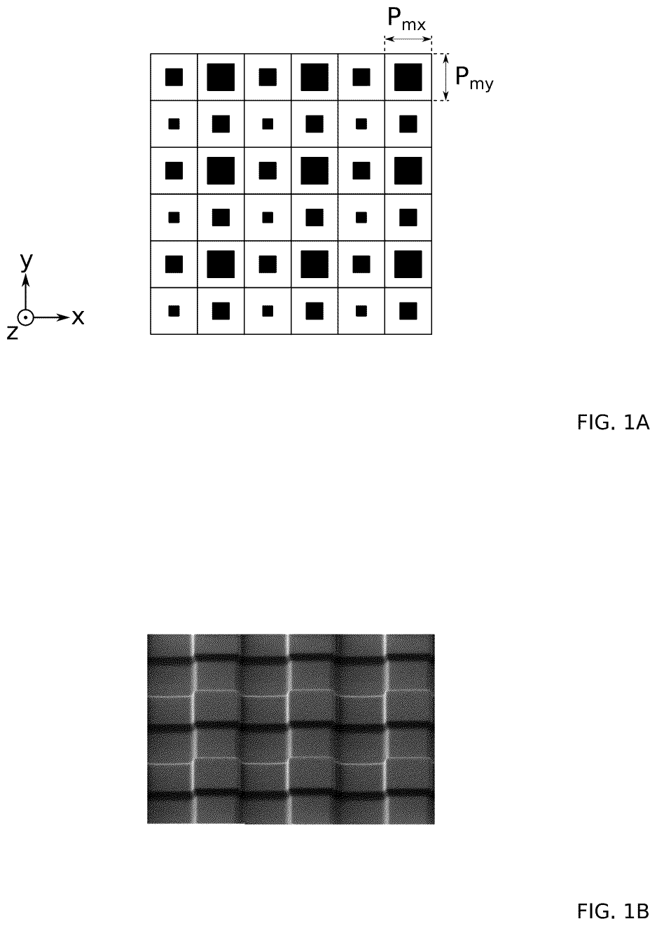

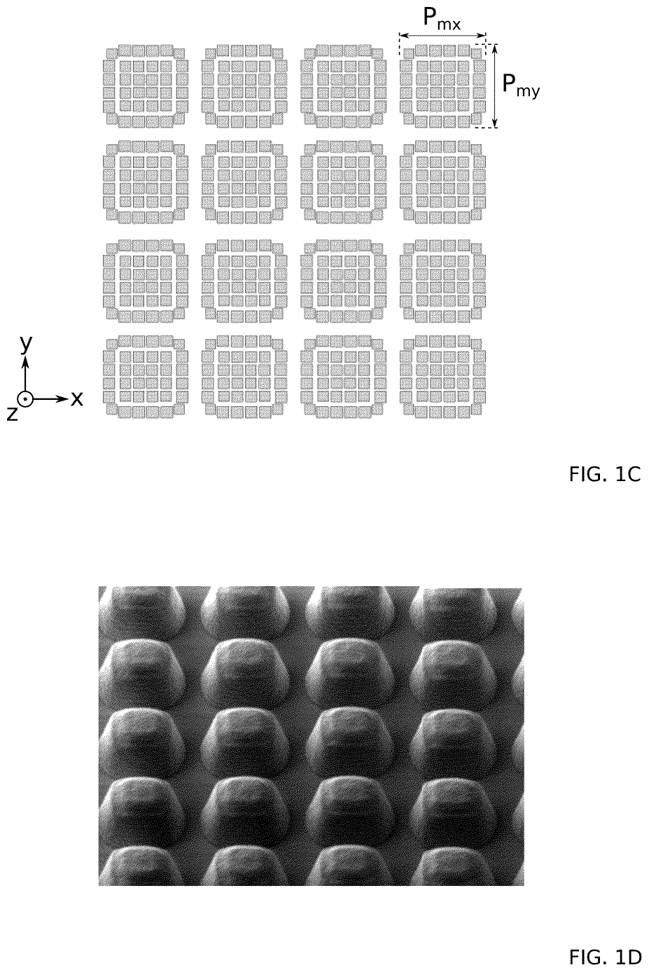

This techniques rests on the fact of making the thickness vary along a dimension Z on which a photosensitive resin is insolated by modulating in the space, the ultraviolet (UV) dose received by the resin. Once the insolated portions are developed, the resin has a 3D structuration (scanning electron microscope (SEM) views) represented in FIGS. 1B and 1D) and can, for example, serve as a mould for manufacturing 3D microstructures.

The ultraviolet dose received locally by the resin can, in particular, be modulated by playing on the dimensions and the positioning of opaque zones present on the lithography mask (FIGS. 1A and 1C). These opaque zones are typically produced by depositing chrome on a glass mask.

Grayscale lithography thus makes it possible to obtain 3D microstructures having a characteristic height going from ten to a few hundreds of micrometres.

The method according to the present invention comprises the following steps:
providing a photosensitive resin 20,
exposing the photosensitive resin to an insolation radiation having been emitted by a light source having a coherence σ and a numerical aperture NA, the insolation radiation having a wavelength λ,
developing the photosensitive resin.

These steps are the conventional steps of a grayscale lithography method. The particularity of the invention resides in the mask used during the step of exposing the photosensitive resin.

The mask used in the method according to the present invention will now be described in reference to the figures, and in particular, to FIG. 14.

The mask 1 extends mainly along a plane (in the example, horizontal) XY defined by the first direction X and the second direction Y. More specifically, it has an upper face 11 and a lower face 12, each extending substantially parallel to the horizontal plane XY.

During using the mask 1, its lower face 12 is placed facing an upper face 21 of a resin layer 20, which can also be referenced resin 20. The upper face 21 of the resin layer 20 itself also extends parallel to the horizontal plane XY. The resin layer 20 typically rests on a support substrate 40. A sublayer 30 can be inserted between the support substrate 40 and the resin layer 20.

During using the mask 1, the resin layer 20 is exposed to a radiation 50 through the mask 1. The radiation 50 is emitted by a light source (not represented) having a coherence σ and a numerical aperture NA.

This radiation 50 has a main direction substantially perpendicular to the horizontal plane XY. The radiation 50 has a wavelength A. It can be a monochrome radiation, in which case A will correspond to the single wavelength emitted. It can, however, also be a polychrome radiation, in which case it is considered that the wavelength A of the radiation is its main wavelength, typically that at which the light intensity is the greatest, or its wavelength average.

The radiation 50 is typically a UV (ultraviolet) radiation; it can thus be a radiation emitting in a wavelength range going from around 100 nm to around 400 nm, for example, 365 nm. It can however also be a radiation having wavelengths located outside of this range. Generally, in a non-limiting manner, a radiation emitting in a wavelength range going from around 90 nm to around 500 nm can be considered.

Ideally, the resin 20 used has at least one of the following features:
a. A substantially linear response between the radiation dose to which it is exposed and the thickness over which it is insolated.
b. A sufficiently low contrast, for example, less than 2, to enable the implementation of grayscale lithography, but sufficiently high, for example, greater than 1, to avoid too high exposure time. Advantageously, the contrast is between 1.1 and 1.5.
c. Good filmogenic properties, guaranteed, for example, by the presence of a filmogenic agent in its composition.
d. A low dissolution inhibition.

In particular, resins, produced by the company Micro Resist Technology having the commercial references ma-P 1215G, ma-P 1225G and ma-P 1275G can be mentioned as examples of resins which can be used in the scope of the invention.

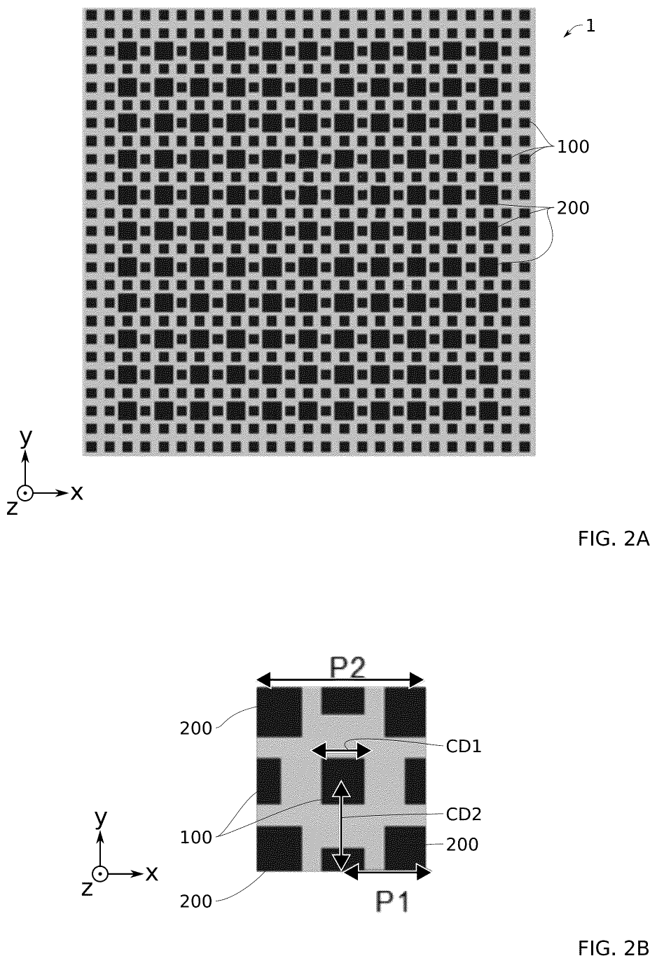

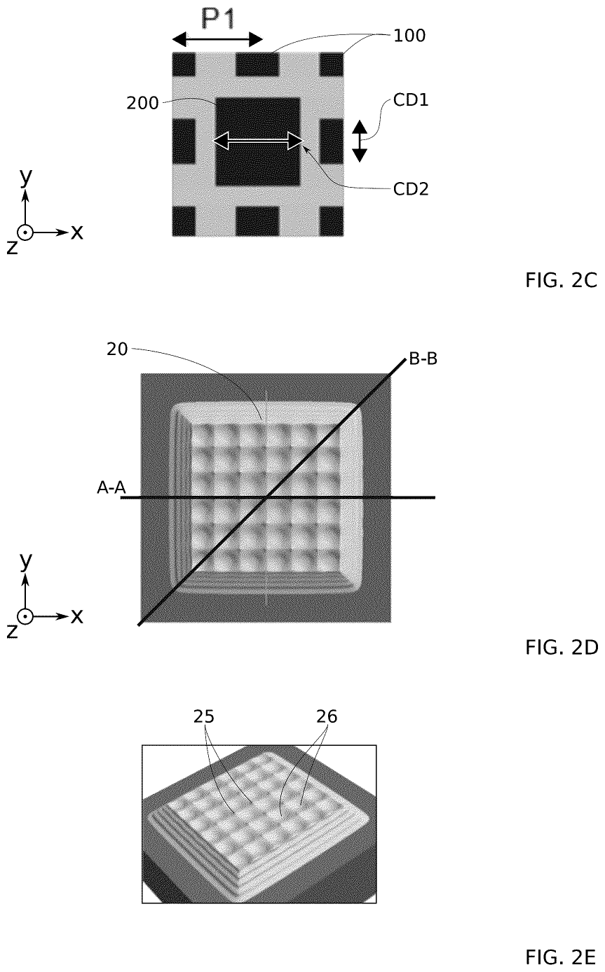

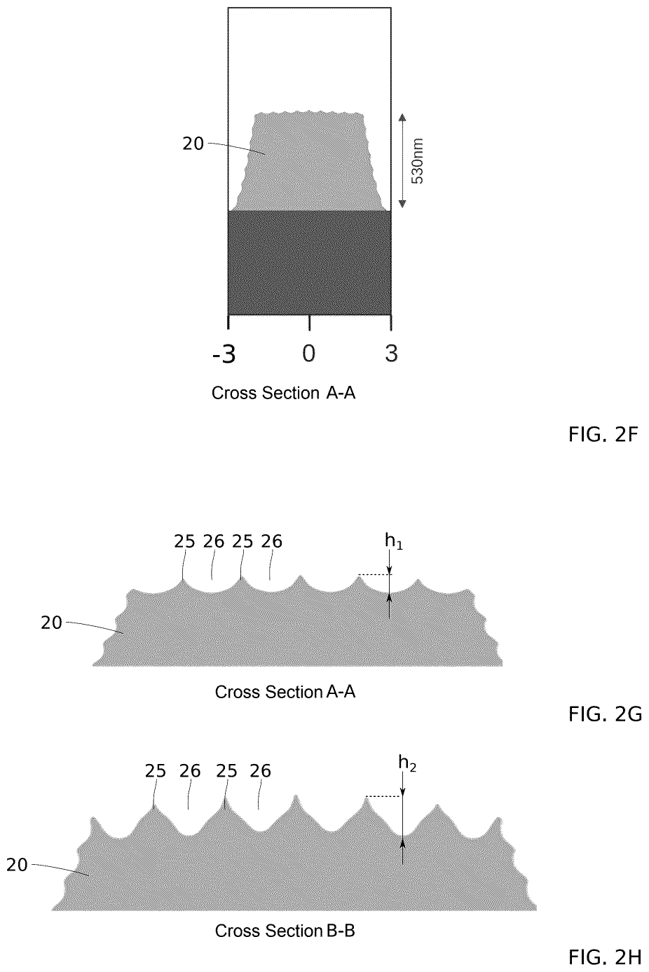

The following paragraphs aim to more specifically describe the mask 1 in reference to the figures, for example, in FIG. 2A.

The mask according to the invention comprises a plurality of opaque zones. Moreover, it comprises transparent zones.

The transparent zones correspond to regions of the mask 1, the composition of which is transparent to the radiation 50, while the opaque zones correspond to regions of the mask 1, the composition of which is opaque to the radiation 50. A zone is, for example, considered as opaque when it stops at least 90% of the incident radiation 50. A zone is considered as transparent when it transmits at least 60% of the incident radiation 50.

For example, the mask 1 can be a glass mask with chrome depositions. The opaque zones thus correspond to the zones of the mask 1 where chrome has been deposited, while the transparent zones correspond to the zones remaining with no chrome.

According to the principle of grayscale lithography, for a given region of the mask 1, the surface density D of the opaque zones within this region determines the dose of radiation received by the region of the underlying resin layer 20 and therefore, consequently, the thickness e over which this region of the resin layer 20 is insolated by the radiation 50. This density D is typically modulated from one region to another of the mask, so as to spatially modulate the thickness insolated in the resin layer 20.

For a given region of the mask 1, the surface density D of the opaque zones is the ratio between the surface of the region occupied by the opaque zones and the total surface of the region. These surfaces can, for example, be evaluated at the lower face 12 of the mask 1, on which material (for example, chrome) depositions are typically performed, forming the opaque zones.

According to the present invention, the plurality of opaque zones comprises at least two arrays of opaque zones formed respectively of first opaque zones 100 and of second opaque zones 200. It is understood that the plurality of opaque zones can comprise other arrays of opaque zones having distinct pitches (see further).

The first opaque zones 100 are distributed in the horizontal plane XY along a pitch array P₁, being able to be referenced first pitch P₁. The first opaque zones 100 have a first characteristic dimension CD1. When the first opaque zones 100 are square-shaped, CD1 corresponds to the side of this square.

The second opaque zones 200 are distributed in the horizontal plane XY along a pitch array P₂, being able to be referenced second pitch P₂. The second opaque zones 200 have a second characteristic dimension CD2. When the second opaque zones 200 are square-shaped, CD2 corresponds to the side of this square.

The first pitch P₁ and the second pitch P₂ moreover respect the following conditions: P₁<P_{Rayleigh} and P₂=P_{Rayleigh}, with:

$${P}_{Rayleigh} = \frac{1}{1 + σ} * \frac{λ}{N A}$$

σ the coherence and NA, the numerical aperture of the light source emitting the radiation 50.

P_{Rayleigh} is referenced the Rayleigh pitch. This is the yield below which the pitch array P does not diffract the incident radiation (diffraction order 0), and above which it diffracts it (diffraction order 1 or more). This constant is specific to the features of the light radiation 50 and of the light source emitting it.

For example, for an incident radiation emitted at a wavelength λ=365 nm and a source of coherence σ=0.7 and of numerical aperture NA=0.7, P_{Rayleigh} is equal to 306 nm.

Thus, in the zones where the first opaque zones 100 are located, the mask 1 does not diffract the incident radiation 50. The radiation 50 is transmitted to the resin 20 without undergoing diffraction. The dose transmitted depends on the density of opaque zones in these zones. It can therefore be modulated by making the pitch P₁ and the dimension CD1 of the first opaque zones 100 vary. The array of first opaque zones thus makes it possible to define a first structuration level.

It is possible that all the first opaque zones 100 are disposed along a constant pitch array P₁ and thus form a regular array (see, for example, FIG. 2A). The regions of the resin insolated by the radiation 50 passing through the first opaque zones 100 thus have, once developed, a planar mean profile. By “mean profile”, this means the profile not considering the nanostructuration described further.

It is also possible that the pitch P₁ varies within the array of first opaque zones 100, while verifying the condition P₁<P_{Rayleigh}. The mean profile of the regions of the resin insolated by the radiation 50 passing through the first opaque zones 100 is thus not constant. It can, for example, have a general convex shape.

It is also possible that the microstructuration is defined by several arrays of opaque zones, and not only the first array of opaque zones 100. These different arrays all having pitches less than P_{Rayleigh} are thus organised, so as to form the desired mean profile in the resin.

The array of first opaque zones 100—and of optional other arrays of opaque zones verifying P<P_{Rayleigh}—thus makes it possible to define the general shape of the resin once developed. This first structuration level can be qualified as microstructuration.

Conversely, in the zones where the second opaque zones are located, the mask 1 diffracts the incident radiation 50. This diffraction causes the concentration of the incident radiation 50 diffracted on certain zones of the resin 20, leading to insolation doses which are locally greater than others. These local variations of insolation doses have the effect, once the resin is revealed, of creating variations of thickness in the resin. This is conveyed by a structuration of this resin. This second structuration level can be qualified as nanostructuration. It is superimposed at the first structuration level.

It is possible that all the second opaque zones 200 are disposed along a constant pitch array P₂ and thus form a regular array.

It is also possible that the pitch P₂ varies within the array of second opaque zones 200, while verifying the condition P₂≥P_{Rayleigh}.

It is also possible that the nanostructuration is defined by several arrays of opaque zones, and not only the second array of opaque zones 200. These different arrays all having pitches greater than or equal to P_{Rayleigh} are thus organised, so as to form the desired nanostructuration in the resin.

All of the figures moreover illustrate the case of square-shaped opaque zones in the horizontal plane XY, but it is understood that other shapes can be considered. The opaque zones can, for example, be rectangular, circular, triangular, hexagonal, oval, or also cross-shaped.

Several configurations of opaque zones will now be described in reference to FIGS. 2A to 14H.

### Example 1: Two Regular Arrays with P₁<P_{Rayleigh}, P₂≥P_{Rayleigh} and P₂=2*P₁

FIGS. 2A to 2H illustrate the case of a mask 1 comprising a regular array of first opaque zones 100, the pitch P₁ of which verifies P₁<P_{Rayleigh}, as well as a regular array of second opaque zones 200, the pitch P₂ of which verifies P₂≥P_{Rayleigh}. FIG. 2A is a general view of the mask, while FIGS. 2B and 2C are magnifications of the mask centred respectively on a first opaque zone 100 and on a second opaque zone 200. In this example, the second opaque zones 200 are each combined with one single first opaque zone 100. The second opaque zones 200 do not overflow over other first opaque zones 100.

In this example, the first opaque zones 100 have a square shape of side CD1 and the second opaque zones 200 have a square shape of side CD2.

Moreover, the following condition has been set in this example: P₂=2*P₁.

More specifically, to perform the simulations, the following values have been set: P₁=300 nm, P₂=600 nm, CD1=150 nm and CD2=200 nm.

FIGS. 2D to 2H are simulation results illustrating the resin obtained after exposure to the radiation 50 through the mask 1 of FIG. 2A and after development. FIG. 2D is a top view of the resin layer and FIG. 2E is a perspective view. FIGS. 2F and 2G (magnification of FIG. 2F) are cross-sectional views of the resin layer along the cross section A-A represented in FIG. 2D. FIG. 2H is a magnification of the cross-sectional view of the resin layer along the cross section B-B represented in FIG. 2D.

It is observed that the regular array of first opaque zones 100 makes it possible to obtain a general plate shape, due to the uniform insolation induced by this regular array. Moreover, the regular array of second opaque zones 200 makes it possible to create a regular structuration of this plate which can be observed in each of FIGS. 2D to 2H. Thus, peaks 25 and troughs 26 are observed on the surface of the resin layer 20. A peak-to-trough height measured along the vertical direction Z between the bottom of the troughs 26 and the height of the peaks 25 is defined. A first peak-to-trough height h₁ is measured at the cross section A-A (FIG. 2G) and a second peak-to-trough height h₂ is measured at the cross section B-B (FIG. 2H). h₁=85 nm and h₂=160 nm are noted. This shows the nanostructuration caused by the array of second opaque zones 200. This nanostructuration is superimposed at the microstructuration: the peaks and troughs are defined with respect to the thickness of the plate that defines the microstructuration.

### Example 2: Two Regular Arrays with P₁<P_{Rayleigh}. P₂≥P_{Rayleigh} and P₂=3*P₁

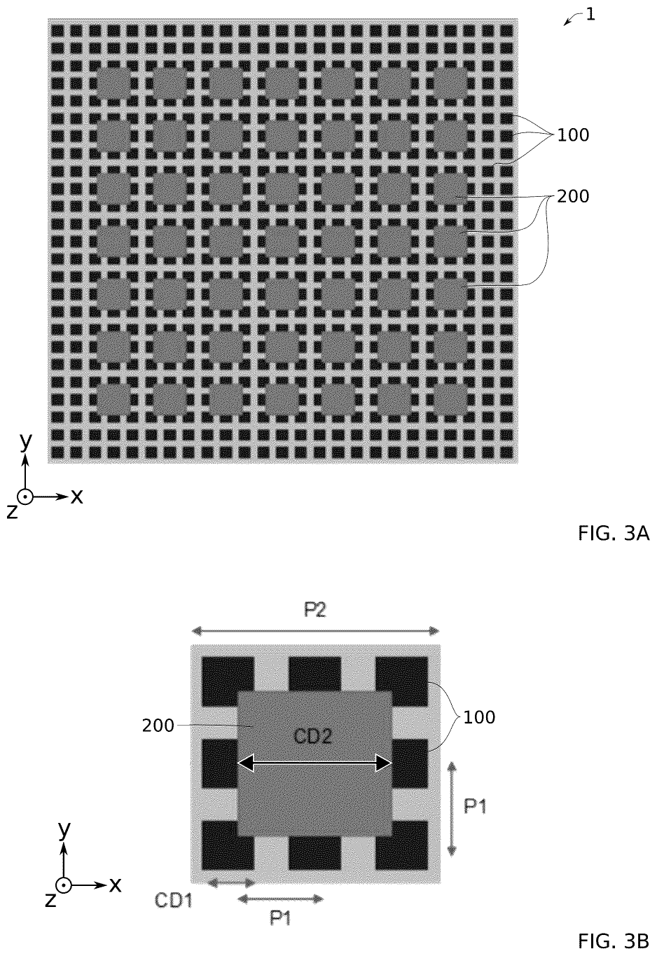

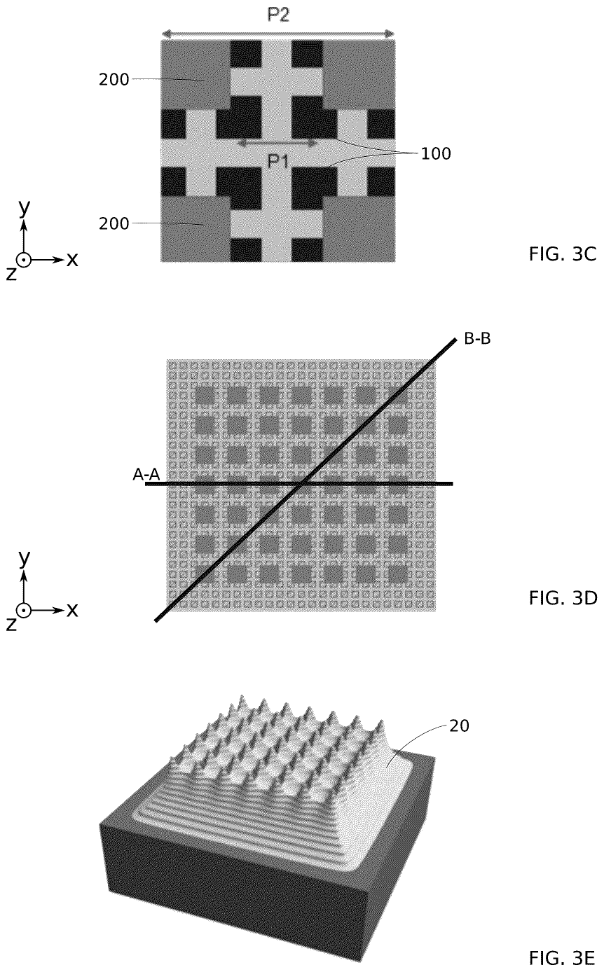

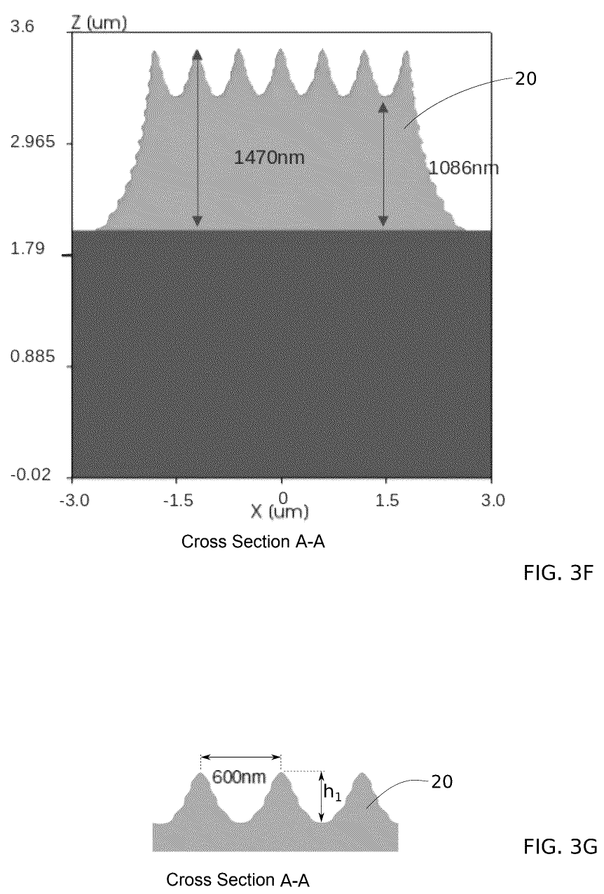

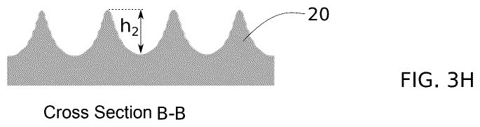

FIGS. 3A to 3H illustrate the case of a mask 1 comprising a regular array of first opaque zones 100, the pitch P₁ of which verifies P₁<P_{Rayleigh}, as well as a regular array of second opaque zones 200, the pitch P₂ of which verifies P₂≥P_{Rayleigh}. FIG. 3A is a general view of the mask, while FIGS. 3B and 3C are magnifications of the mask centred respectively on a second opaque zone 200 and on four first opaque zones 100. In this example, the second opaque zones 200 are each combined with a first opaque zone 100 and are also partially combined with the immediately neighbouring eight first opaque zones 100.

In this example, the first opaque zones 100 have a square shape of side CD1 and the second opaque zones 200 have a square shape of side CD2.

Moreover, the following conditions has been set in this example: P₂=3*P₁.

More specifically, to perform the simulations, the following values have been set: P₁=200 nm, P₂=600 nm, CD1=118.4 nm and CD2=200 nm.

FIGS. 3D to 3H are simulation results illustrating the resin obtained after exposure to the radiation 50 through the mask 1 of FIG. 3A and after development. FIG. 3D is a top view of the resin layer and FIG. 3E is a perspective view. FIGS. 3F and 3G (magnification of FIG. 3F) are cross-sectional views of the resin layer along the cross section A-A represented in FIG. 3D. FIG. 3H is a magnification of the cross-sectional view of the resin layer along the cross section B-B represented in FIG. 2D.

Like in the preceding example, the regular array of first opaque zones 100 makes it possible to obtain a general plate shape and the regular array of second opaque zones 200, a regular structuration of this plate which can be observed in each of FIGS. 2D to 2H. This time, h₁=600 nm (FIG. 3G) and h₂=614 nm (FIG. 3H) are noted.

The two preceding examples illustrate how it is possible, by imposing that P₂ is a multiple of P₁ (P₂=2*P₁, P₂=3*P₁ . . . ), to create a regular nanostructuration, with peaks 25 of the same height over the entire surface of the resin 20.

### Example 3: Two Regular Arrays with P₁<P_{Rayleigh}, P₂≥P_{Rayleigh} and P₂=2.5*P₁

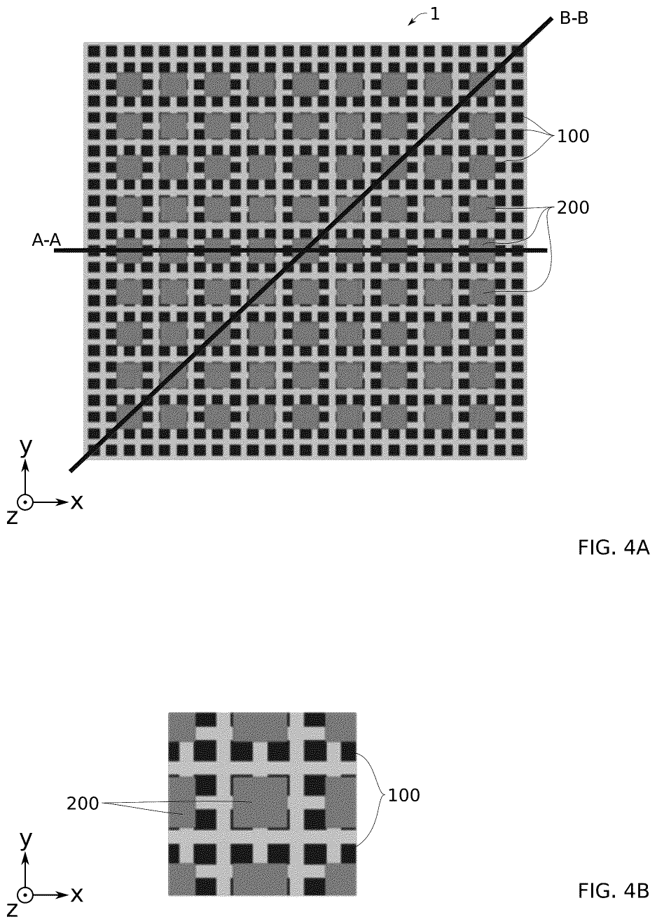

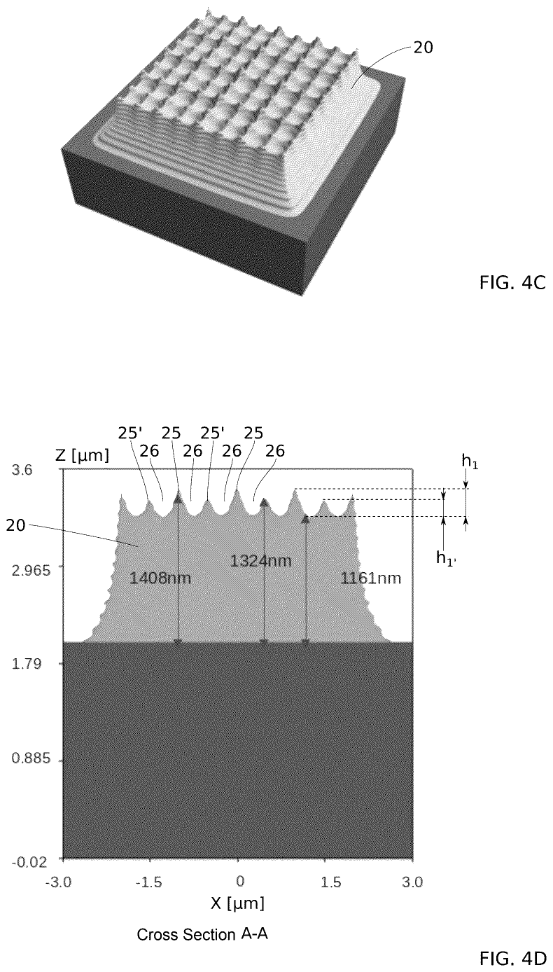

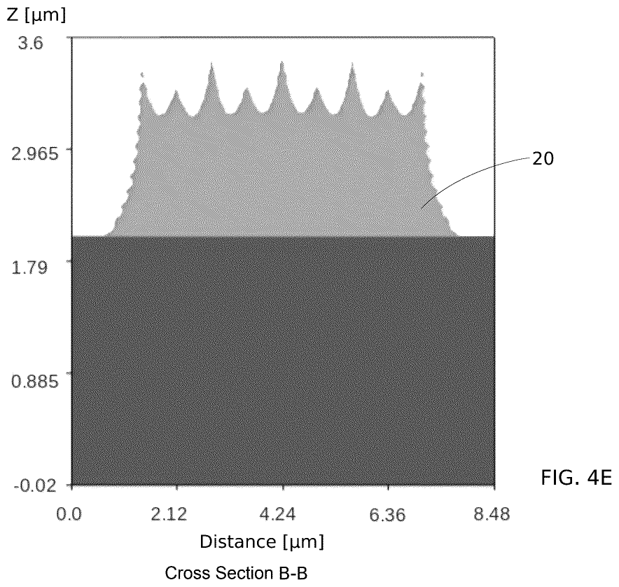

FIGS. 4A to 4E illustrate the case of a mask 1 comprising a regular array of first opaque zones 100, the pitch P₁ of which verifies P₁<P_{Rayleigh}, as well as a regular array of second opaque zones 200, the pitch P₂ of which verifies P₂≥P_{Rayleigh}. FIG. 4A is a general view of the mask 1, while FIG. 4B is a magnification of the mask 1 centred on a second opaque zone 200. In this example, the second opaque zones 200 are, alternately, partially combined with four or six first opaque zones 100 (see FIGS. 4A and 4B: FIG. 4B is, for example, centred on a second opaque zone 200 combined with four first opaque zones 100).

In this example, the first opaque zones 100 have a square shape of side CD1 and the 30 second opaque zones 200 have a square shape of side CD2.

Moreover, the following condition has been set in this example: P₂=2.5*P₁.

More specifically, to perform the simulations, the following values have been set: P₁=200 nm, P₂=500 nm, CD1=118 nm and CD2=295 nm.

FIGS. 4C to 4E are simulation results illustrating the resin obtained after exposure to the radiation 50 through the mask 1 of FIG. 4A and after development. FIG. 4C is a perspective view of the resin layer. FIGS. 4D and 4E are cross-sectional views of the resin respectively along the cross section A-A and along the cross section B-B represented in FIG. 4A.

Like in the preceding example, the regular array of first opaque zones 100 makes it possible to obtain a general plate shape and the regular array of second opaque zones 200, a regular structuration of this plate which can be observed in each of FIGS. 4C to 4E.

Due to the condition P₂=2.5*P₁, main peaks 25 and secondary peaks 25′ are observed, less high than the main peaks 25. Along the cross section A-A, a peak-to-trough height h₁ is thus defined for the main peaks 25 (h₁=247 nm) and a peak-to-trough height h₁′ for the secondary peaks 25′ (h₁′=163 nm).

This example thus illustrates how it is possible, by imposing that P₂ is a multiple of P₁ modulo 0.5*P₁ (P₂=2.5*P₁, P₂=3.5*P₁ . . . ), to create a regular nanostructuration, with peaks 25, 25′ of two different heights on the surface of the resin 20.

### Example 4: Three Regular Arrays with P₁<P_{Rayleigh}, P₂, P₃≥P_{Rayleigh} and P₂=2*P₁ and P₃=3*P₁

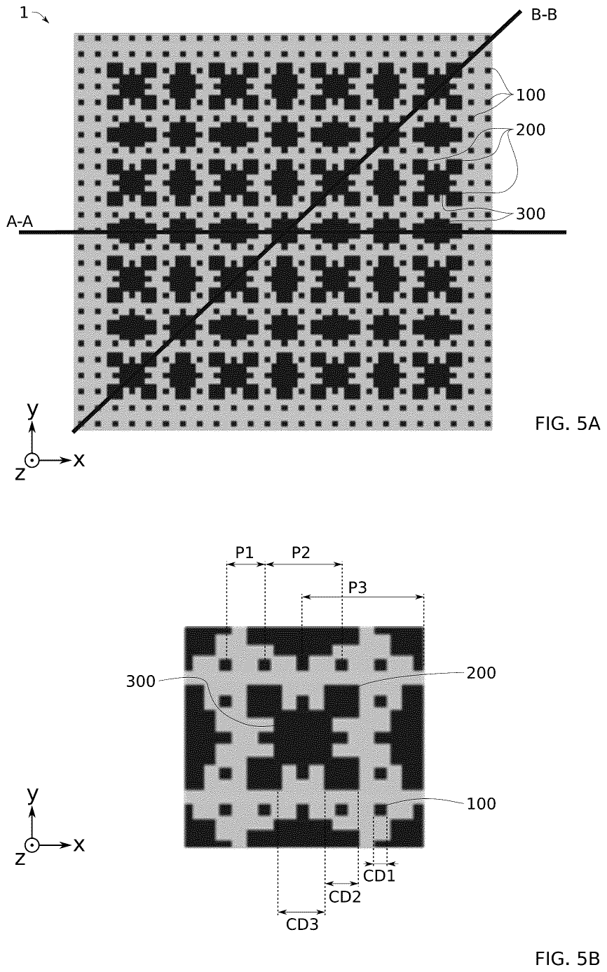

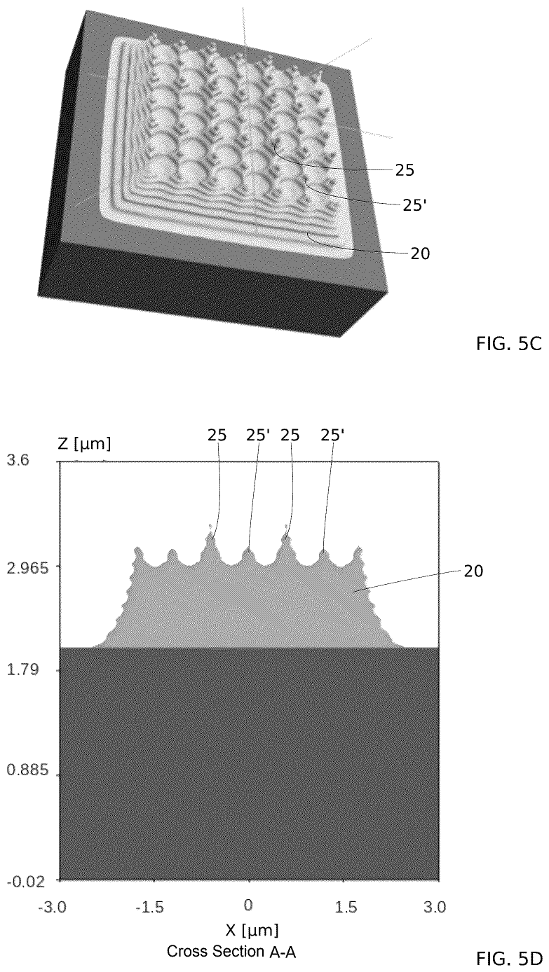

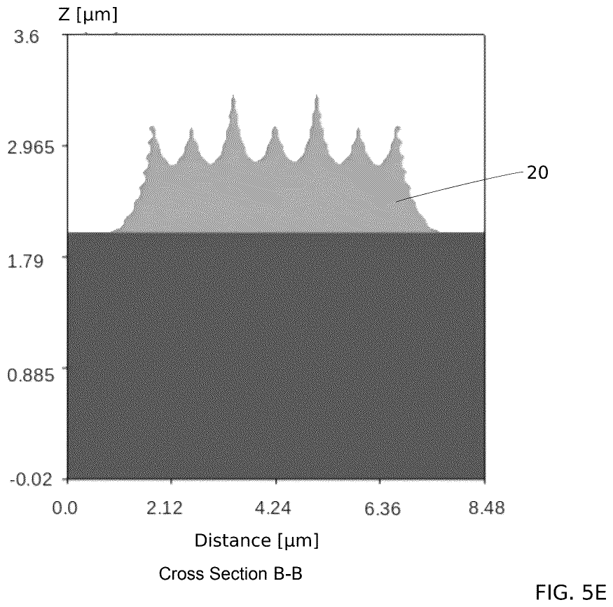

FIGS. 5A to 5E illustrate the case of a mask 1 comprising a regular array of first opaque zones 100, the pitch P₁ of which verifies P₁<P_{Rayleigh}, as well as a regular array of second opaque zones 200 and a regular array of third opaque zones 300, the respective pitches P₂ and P₃ of which verify P₂≥P_{Rayleigh} and P₃≥P_{Rayleigh}. FIG. 5A is a general view of the mask 1, while FIG. 5B is a magnification of the mask 1 centred on a third opaque zone 300.

In this example, the first opaque zones 100 have a square shape of side CD1, the second opaque zones 200 have a square shape of side CD2 and the third opaque zones 300 have a square shape of side CD3.

Moreover, the following conditions have been set in this example: P₂=2*P₁ and P₃=3*P₁.

More specifically, to perform the simulations, the following values have been set: P₁=200 nm, P₂=400 nm, P₂=600 nm, CD1=118 nm, CD2=236 nm and CD3=355 nm.

FIGS. 5C to 5E are simulation results illustrating the resin obtained after exposure to the radiation 50 through the mask 1 of FIG. 5A and after development. FIG. 5C is a perspective view of the resin layer. FIGS. 5D and 5E are cross-sectional views of the resin, respectively along the cross section A-A and along the cross section B-B represented in FIG. 5A.

Like in the preceding examples, the regular array of first opaque zones 100 makes it possible to obtain a general plate shape. The regular structuration of this plate which can be observed in each of FIGS. 5C to 5E is, this time, due to the regular array of second opaque zones 200, as well as to the regular array of third opaque zones 300.

The presence of two arrays of opaque zones, the pitch of which is greater than the Rayleigh pitch enables a more complex nanostructuration than in the case of one single array of opaque zones verifying this condition. In particular, main peaks 25 and second peaks 25′ are observed, less high than the main peaks 25.

This example thus illustrates how it is possible, by resorting to several arrays of opaque zones having a pitch greater than the Rayleigh pitch, to create a regular nanostructuration, with peaks 25, 25′ of different heights on the surface of the resin 20.

### Examples 5, 6, 7 and 8: Irregular Array with Local Augmentation of the Pitch

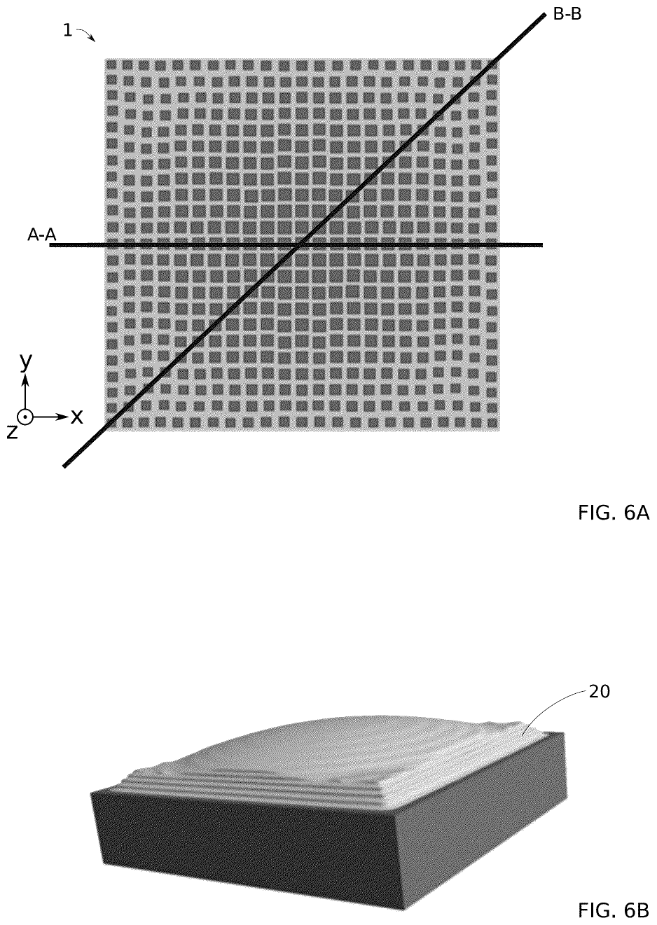

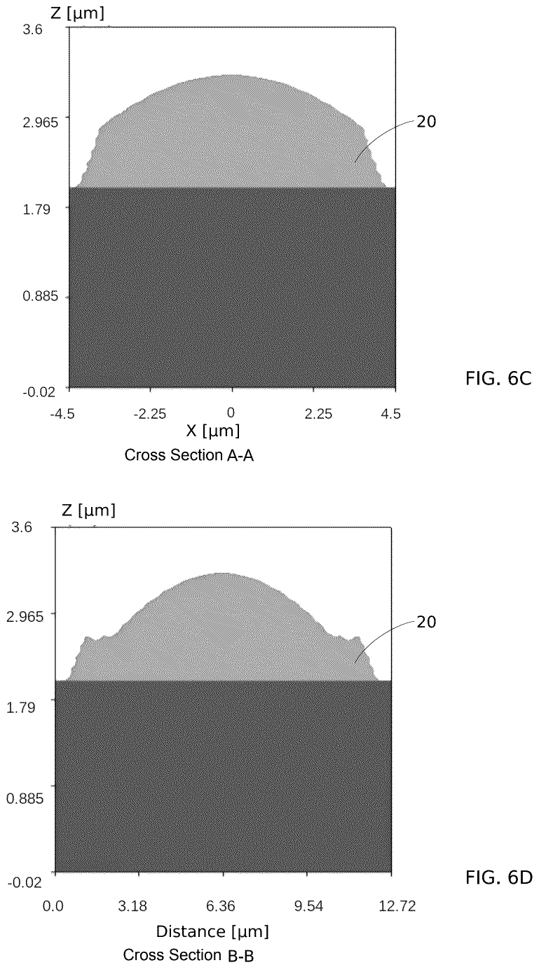

FIGS. 6A to 6D illustrate a mask 1 (FIG. 6A), the density of which of the opaque zones is modulated, such that, once developed, the resin has a dome shape (FIGS. 6B, 6C, 6D). The following three examples combine this principle with the principle of the present invention to perform a nanostructuration on a first dome-shaped structuration.

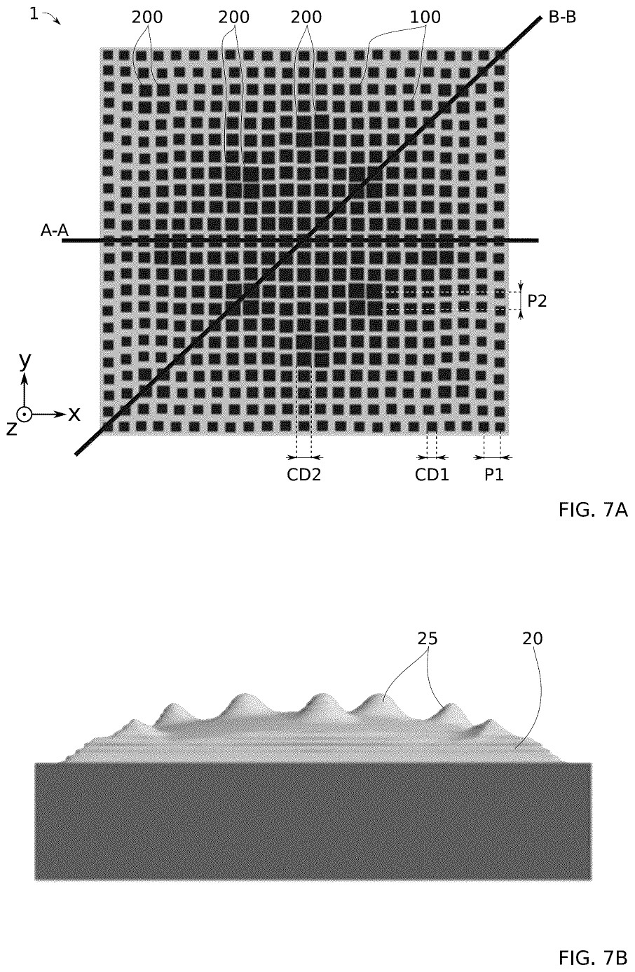

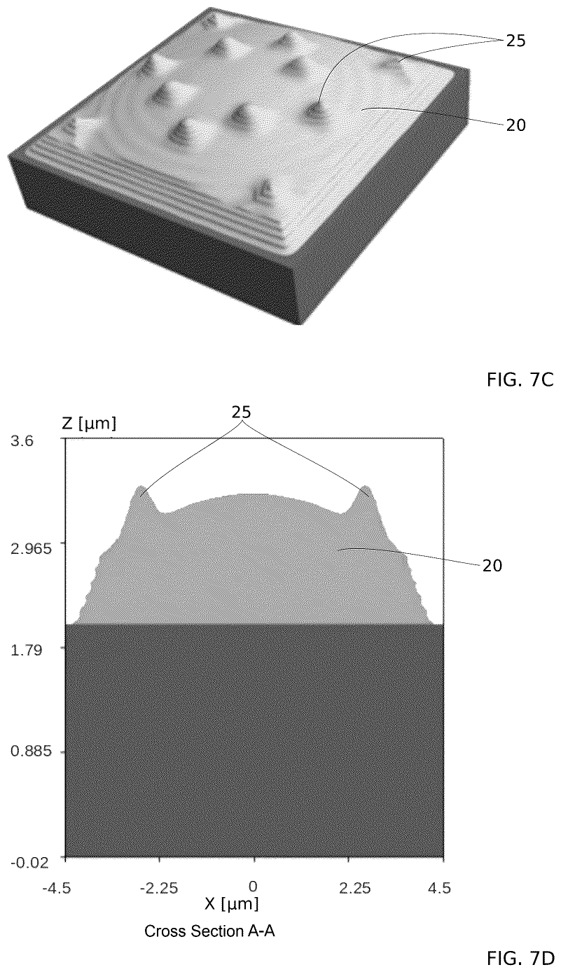

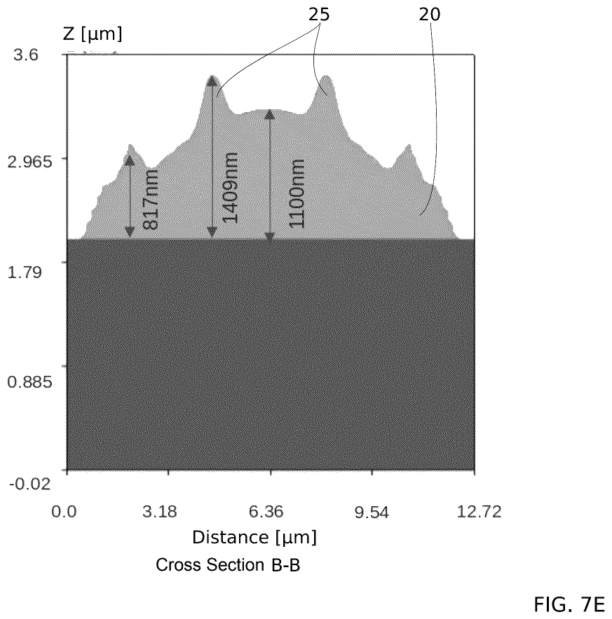

FIGS. 7A to 7E illustrate the case of a mask 1 comprising an array of first opaque zones 100, the variable pitch P₁ of which verifies P₁<P_{Rayleigh} in the entire array. The mask 1 moreover comprises an array of second opaque zones 200, the pitch P₂ of which verifies P₂≥P_{Rayleigh}.

In this example, the first opaque zones 100 have a variable square shape of side CD1 and the second opaque zones 200 have an optionally variable square shape of side CD2. Moreover, CD2 is greater than CD1 in this example.

FIG. 7A is a general view of the mask. FIGS. 7B to 7E are simulation results illustrating the resin obtained after exposure to the radiation 50 through the mask 1 of FIG. 7A and after development. FIG. 7C is a perspective view of the resin layer and FIG. 7B is a profile view. FIGS. 7D and 7E are cross-sectional views of the resin layer respectively along the cross section A-A and along the cross section B-B represented in FIG. 7A.

The array of first opaque zones 100 makes it possible to obtain a general dome shape and the array of second opaque zones 200, a nanostructuration of the dome which can be observed in each of FIGS. 7B to 7E. The fact that, in this example, CD2 is greater than CD1 induces a nanostructuration in the form of peaks 25. These peaks 25 project with respect to the general dome shape induced by the array of first opaque zones 100.

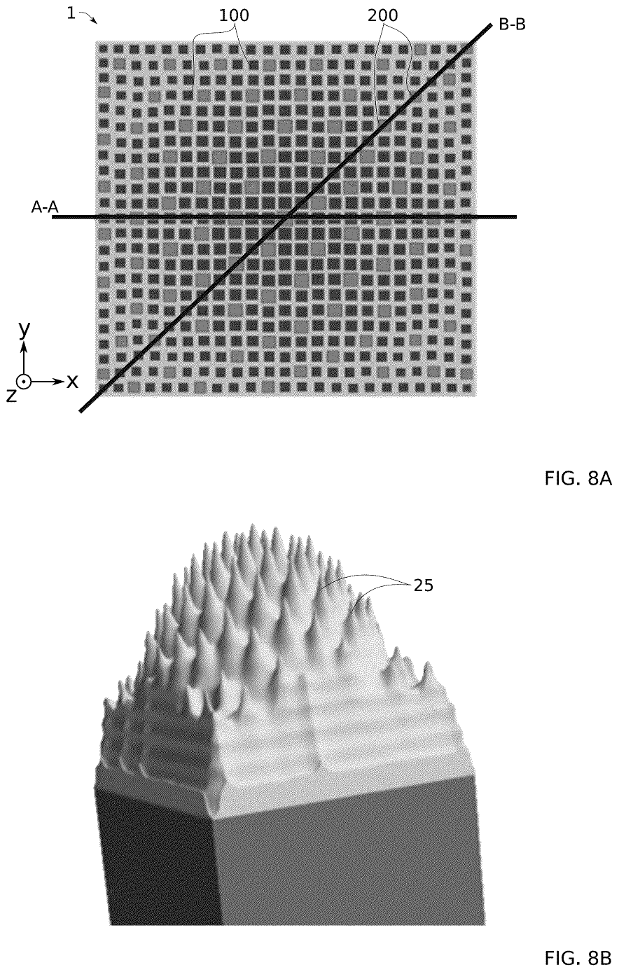

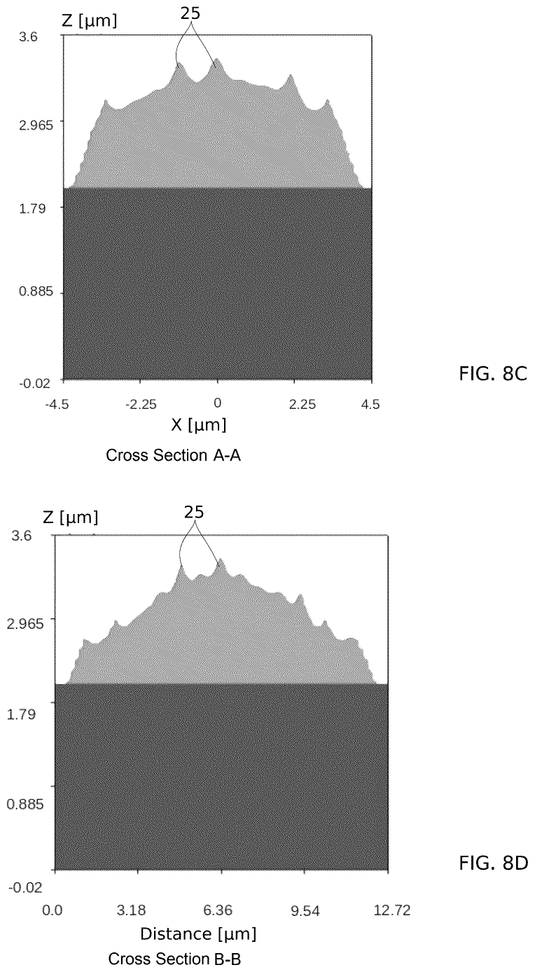

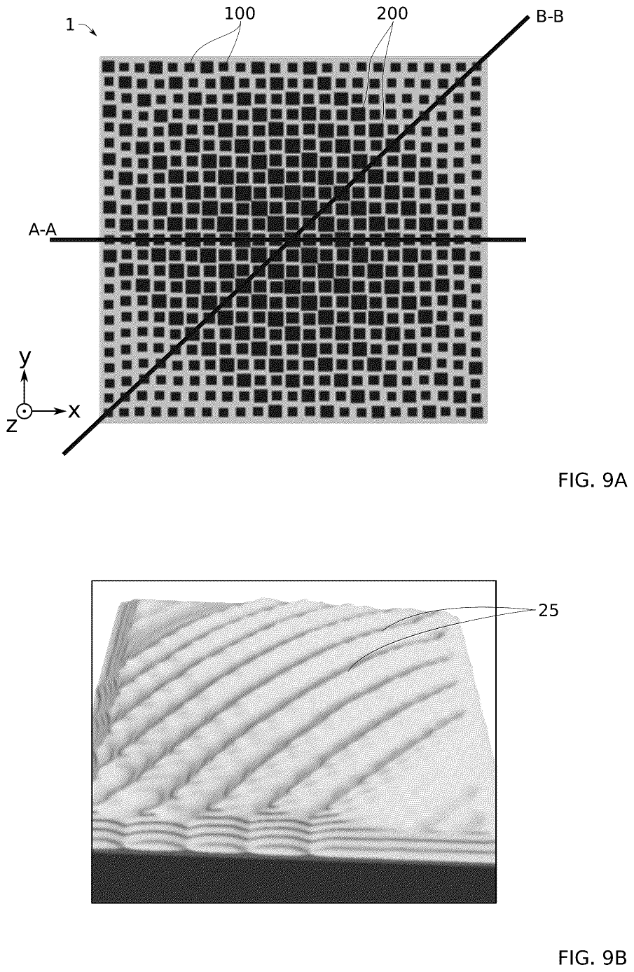

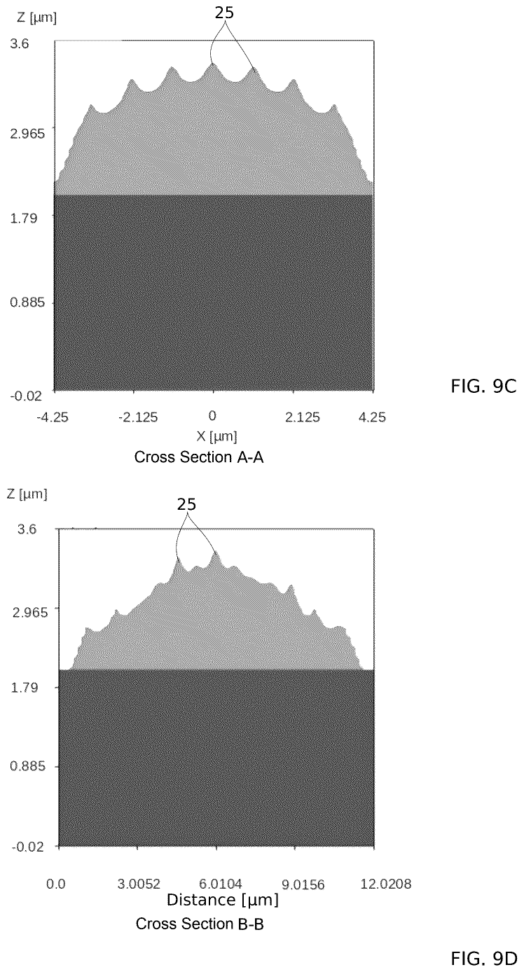

Two other very similar examples are illustrated in FIGS. 8A to 8D, on the one hand, and 9A to 9D on the other hand. These examples differ from the preceding example through the positioning of the second opaque zones 200 on the mask 1. In the example illustrated in FIGS. 8A to 8D, the second opaque zones are distributed regularly over the entire surface of the mask 1. The formation of as many peaks 25 as second opaque zones 200 is observed on the simulation results (FIGS. 8B, 8C, 8D). In the example illustrated in FIGS. 9A to 9D, the second opaque zones 200 are aligned along axes parallel to a diagonal of the mask 1. The formation of as many peaks 25 or ridges 25 as rows of second opaque zones 200 are observed on the simulation results (FIGS. 9B, 9C, 9D). In both cases, the nanostructuration is added to the dome-shaped microstructuration induced by the array of first opaque zones 100.

### Example 9: Irregular Array with Local Diminution of the Pitch

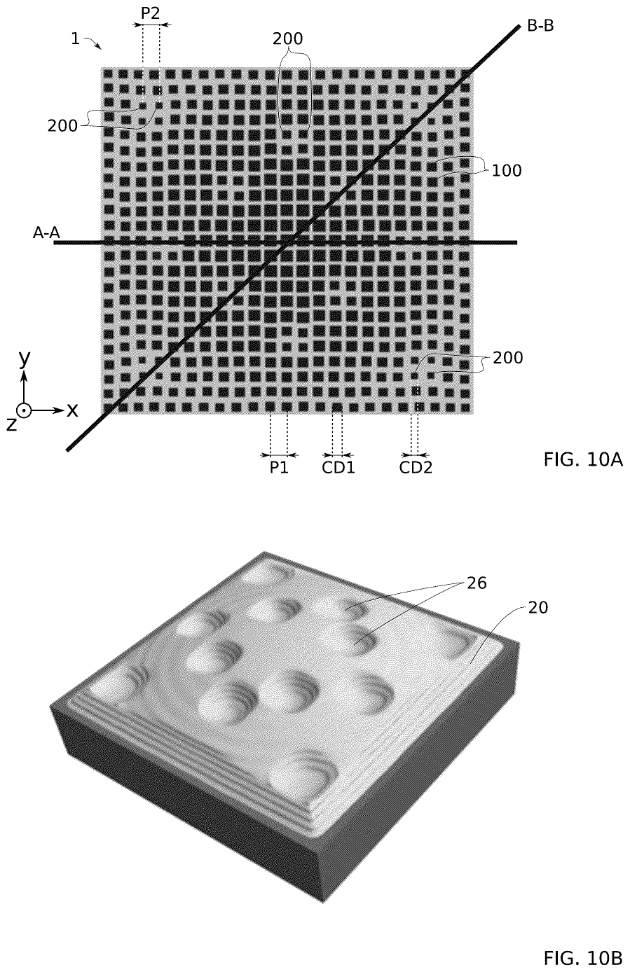

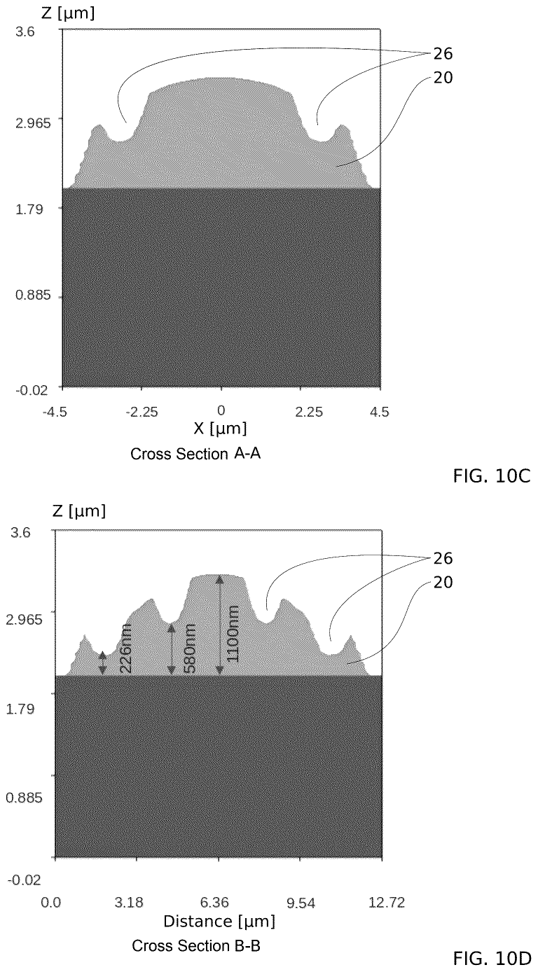

Another example is illustrated in FIGS. 10A to 10D (FIG. 10A: general view of the mask, FIG. 10B: perspective view of the insolated and developed resin, FIGS. 10C and 10D: views along the cross sections A-A and B-B). It is differentiated from the two preceding examples, in that CD2 is less than CD1. The nanostructuration caused by the second opaque zones is conveyed, this time, by troughs 26. These troughs 26 are defined recessed with respect to the general dome shape induced by the array of first opaque zones 100.

### Example 10: Superimposition of an Irregular Array with P₁<P_{Rayleigh} and of a Regular Array with P₂≥P_{Rayleigh}

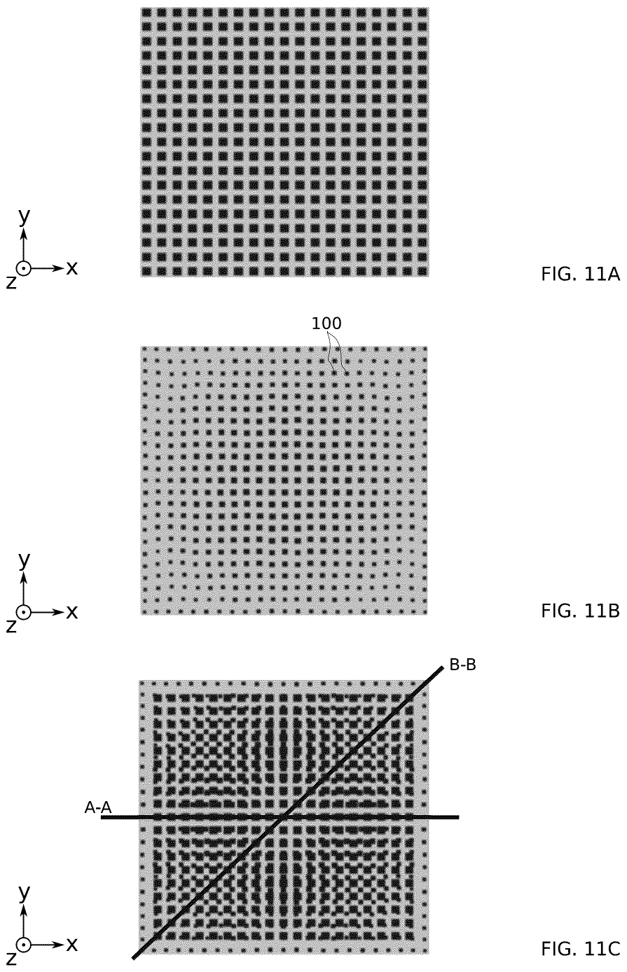

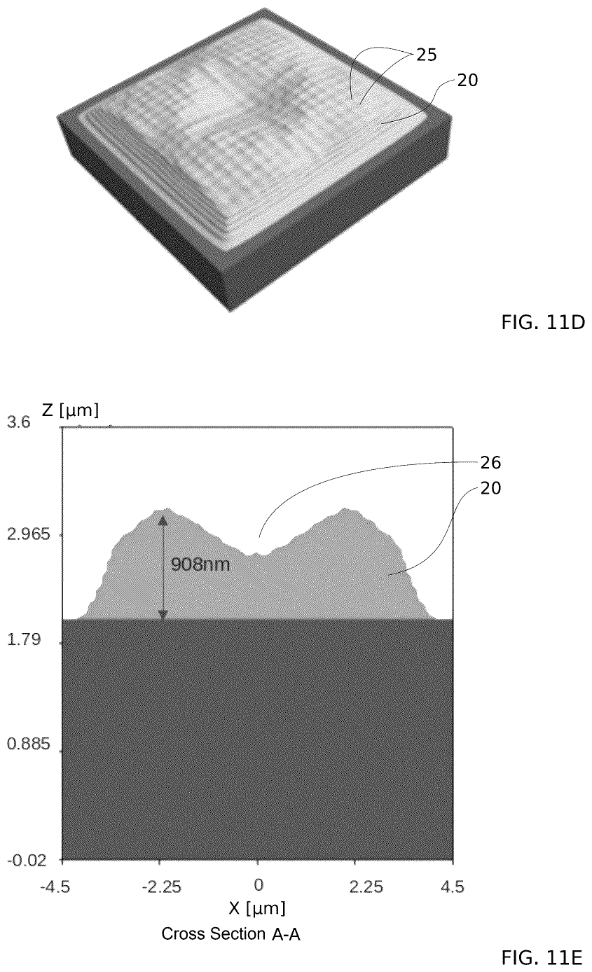

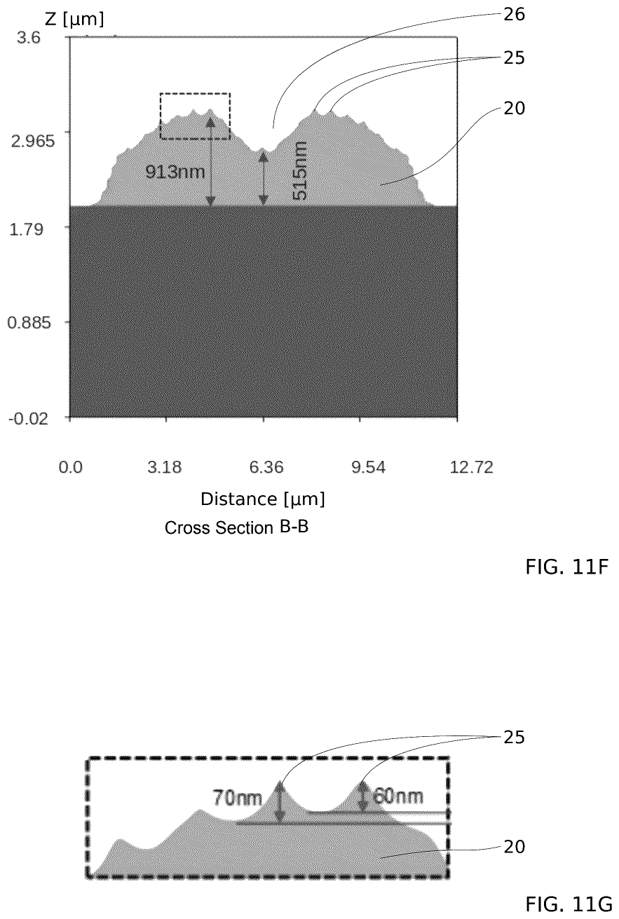

FIGS. 11A to 11F illustrate the case of a mask 1 comprising an irregular array of first opaque zones 100, the variable pitch P₁ of which verifies P₁<P_{Rayleigh} over the entire array (FIG. 11B), as well as a regular array of second opaque zones 200, the pitch P₂ of which verifies P₂≥P_{Rayleigh} (FIG. 11A). FIG. 11C is a general view of the mask, which corresponds to the superimposition of the two arrays illustrated in FIGS. 11A and 11B.

In this example, the first opaque zones 100 have a variable square shape of side CD1 and the second opaque zones 200 have a square shape of side CD2.

FIGS. 11D to 11G are simulation results illustrating the resin obtained after exposure to the radiation 50 through the mask 1 of FIG. 11C and after development. FIG. 11D is a perspective view of the resin layer 20. FIG. 11E is a cross-sectional view of the resin layer along the cross section A-A represented in FIG. 11C. FIGS. 11F and 11G (magnification of FIG. 11F) are cross-sectional views of the resin layer along the cross section B-B represented in FIG. 11C.

The array of first opaque zones 100 makes it possible to obtain a general dome shape and the array of second opaque zones 200, a nanostructuration of the dome (see peaks 25) which can observed in each of FIGS. 11D to 11F.

Moreover, it is noted that the relative arrangement of the arrays of opaque zones causes a high transmission of the radiation 50 to the centre of the resin layer 20, thus locally inducing a low resin thickness (see FIG. 11F, in particular: thickness of 515 nm). The trough 26 thus formed defines an intermediate structuration level being able to be utilised to produce certain complex shapes.

### Example 11: Superimposition of an Irregular Array with P₁<P_{Rayleigh} and of a Regular Cross-Shaped Array with P₂=P_{Rayleigh}

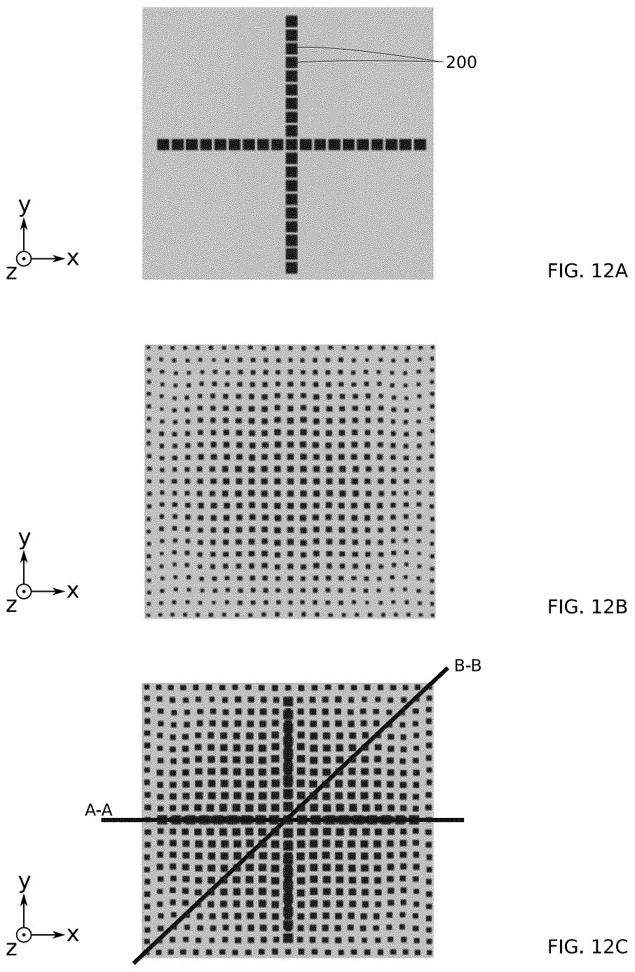

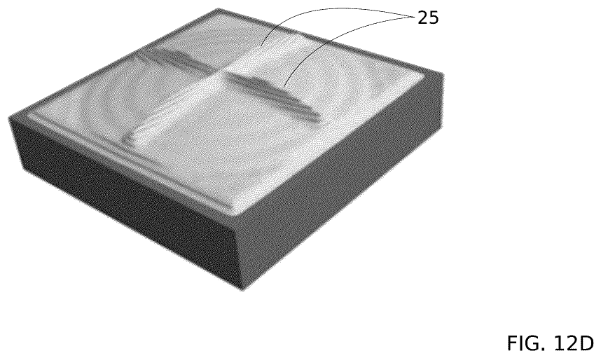

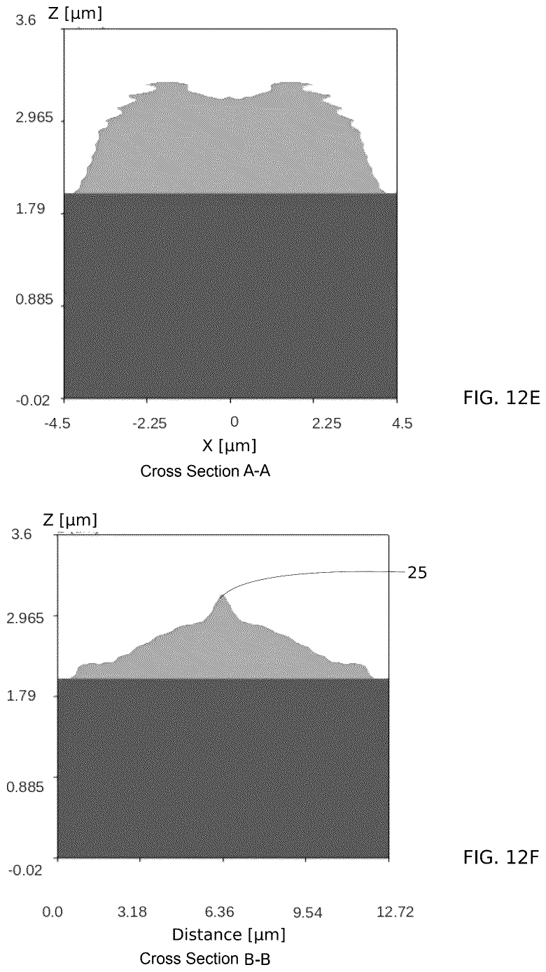

Another very similar example is illustrated in FIGS. 12A to 12F. In this example, the second opaque zones 200 are not distributed regularly over the entire surface of the mask 1 like in the preceding example, but are distributed, so as to form a cross (see FIG. 12A). The mask 1 (FIG. 12C) is thus formed from the superimposition of this regular cross-shaped array verifying P₂≥P_{Rayleigh} (FIG. 12A) and of the irregular array of first opaque zones verifying P₁<P_{Rayleigh}.

Not only the dome-shaped microstructuration induced by the first array of opaque zones, but also a nanostructuration of this dome, the shape of which follows the general shape of the array of second opaque zones 200 are observed on the simulation results (see in FIG. 12D the ridges 25 themselves also forming a cross).

FIG. 12E is a cross-sectional view of the resin layer along the cross section A-A represented in FIG. 12C. FIG. 12F is a cross-sectional view of the resin layer along the cross section B-B represented in FIG. 12C.

### Example 12: Superimposition of an Irregular Array with P₁<P_{Rayleigh} and of Two Regular Arrays with P₂, P₃≥P_{Rayleigh}, One of which Cross-Shaped

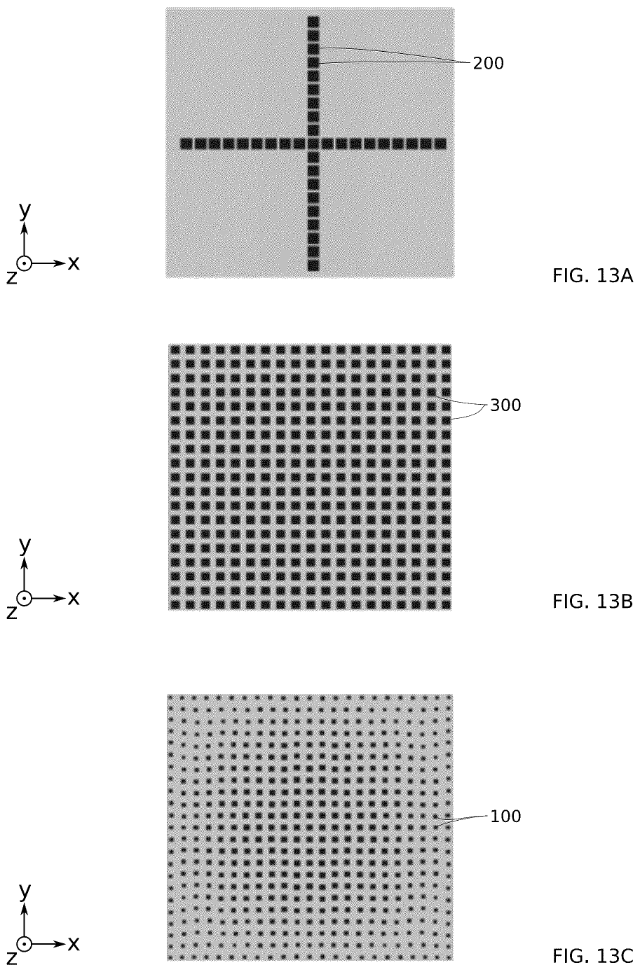

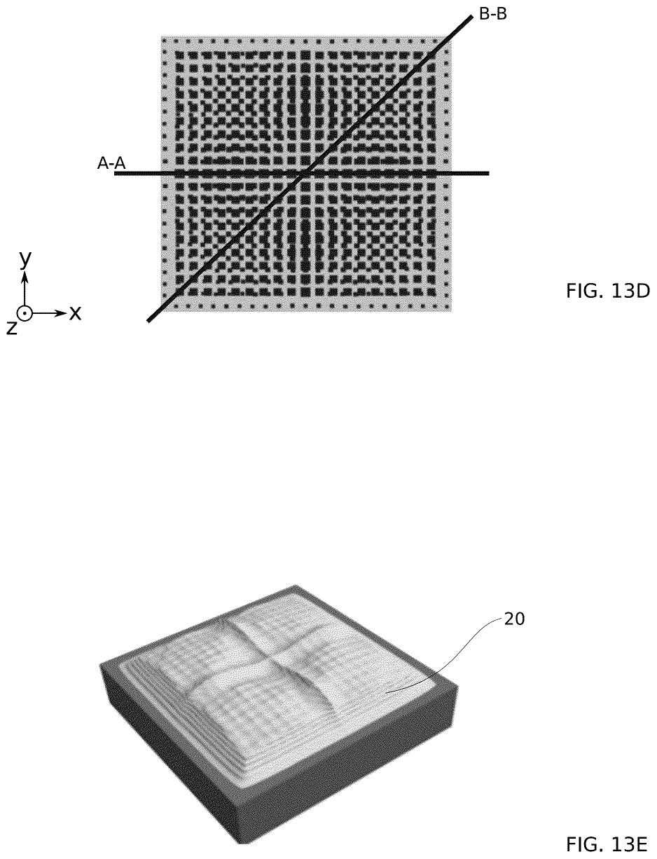

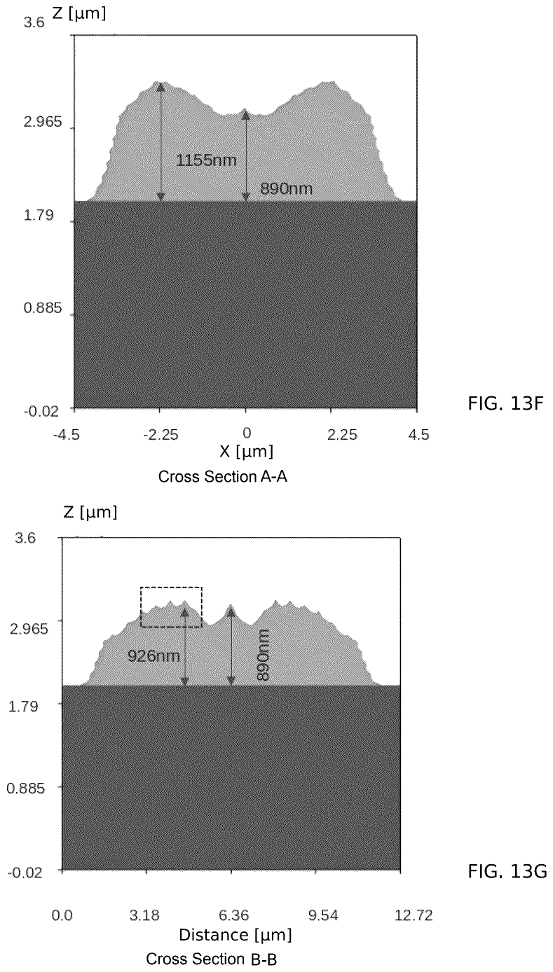

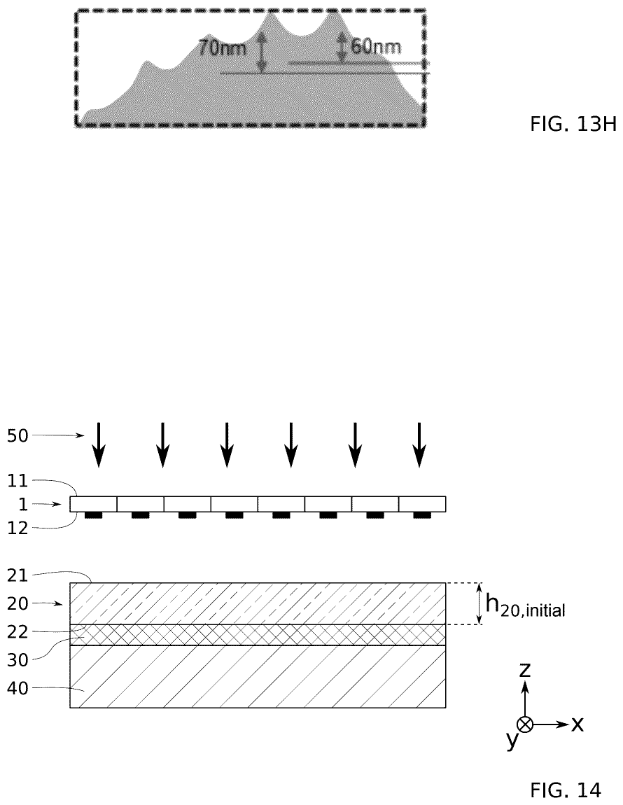

Another example is illustrated in FIGS. 13A to 13G. With respect to the preceding example, a regular array of third opaque zones 300, the pitch P₃ of which verifies P₃≥P_{Rayleigh} (FIG. 13B) has been added.

Again, the array of first opaque zones 100 gives a general dome shape to the resin 20, while the two arrays of opaque zones, the pitch of which is greater than the Rayleigh pitch induce a nanostructuration of this dome. The regular array of the third zone induces the presence of regular peaks over the entire surface of the resin, while the regular cross-shaped array induces a structuration, itself also cross-shaped (see FIG. 13E, in particular).

Through different embodiments described above, it appears that the present invention enables the formation in a photosensitive resin layer of a double structuration along varied patterns.

The invention is not limited to the embodiments described above, and extends to all the embodiments covered by the invention.

1. A method for insolating a photosensitive resin comprising the following steps:
providing a photosensitive resin,
exposing the photosensitive resin to an insolation radiation having been emitted by a light source having a coherence σ and a numerical aperture NA, the insolation radiation having a wavelength 2,
developing the photosensitive resin,
the exposure of the photosensitive resin to the insolation radiation being done through a grayscale lithography mask, extending mainly along a horizontal plane defined by a first direction and a second direction, the horizontal plane being perpendicular to a main direction of the insolation radiation of the photosensitive resin through the mask, the mask comprising a plurality of zones which are opaque to the radiation, the plurality of opaque zones comprising first opaque zones and second opaque zones, the first opaque zones being organised along a pitch array P₁ in the horizontal plane and the second opaque zones being organised along a pitch array P₂ in the horizontal plane, such that P₁<P_{Rayleigh} and P₂≥P_{Rayleigh}, with
$${P}_{Rayleigh} = \frac{1}{1 + σ} * \frac{λ}{NA}$$
such that, after the development of the photosensitive resin, the photosensitive resin has a first structuration level and a second structuration level superimposed on one another.

2. The method according to claim 1, wherein the first opaque zones are substantially identical to one another.

3. The method according to claim 1, wherein the first opaque zones have dimensions which are distinct from one another.

4. The method according to claim 1, wherein the second opaque zones are substantially identical to one another.

5. The method according to claim 1, wherein some of the first opaque zones and of the second opaque zones are at least partially combined.

6. The method according to claim 1, wherein P₂=2*m*P₁, m being an integer.

7. The method according to claim 1, wherein P₂=3*m*P₁, m being an integer.

8. The method according to claim 1, wherein P₂=2.5*m*P₁, m being an integer.

9. The method according to claim 1, wherein the plurality of opaque zones further comprises third opaque zones organised along a pitch array P₃ in the horizontal plane, P₃ being distinct from P₁ and from P₂.

10. The method according to claim 9, wherein P₃≥P_{Rayleigh}.

11. The method according to claim 2, wherein P₃=3*n*P₁, n being an integer.

12. The method according to claim 1, wherein the plurality of opaque zones allows at least one first symmetry plane perpendicular to the horizontal plane.

13. The method according to claim 12, wherein the plurality of opaque zones allows at least one second symmetry plane perpendicular to the first symmetry plane and to the horizontal plane.

14. The method according to claim 1, wherein P₁ is less than or equal to 300 nm, for example, equal to 200 nm.

15. The method according to claim 1, wherein P₂ is greater than or equal to 400 nm, for example, equal to 400 nm, 500 nm or 600 nm.
